(19) United States
(12) Patent Application Publication
(10) Pub. No.: US 2012/0153438 A1
(43) Pub. Date: Jun. 21, 2012

(54) MULTIPLE NOBLE METALS FOR LIFETIME SUPPRESSION FOR POWER SEMICONDUCTORS

(75) Inventor: Allan Harrison, Brea, CA (US)

(73) Assignee: SOLID STATE DEVICES, INC., La Mirada, CA (US)

(21) Appl. No.: 13/169,390

(22) Filed: Jun. 27, 2011

Related U.S. Application Data
(60) Provisional application No. 61/424,015, filed on Dec. 16, 2010.

(51) Int. Cl. H01L 29/36; H01L 21/225

(52) U.S. Cl. 257/610; 438/548; 257/E29.109; 257/E21.144

(57) ABSTRACT

Certain embodiments combine the use of two or more noble metal impurities (e.g., gold, platinum, palladium, iridium, etc.) to suppress the lifetime of power semiconductors such as diodes. The noble metals may be applied using various methods including, for example, the application of thin films from a liquid suspension of the noble metals (e.g., gold and platinum) and/or alloys thereof onto the wafer and/or the coating the wafer with a layer of the noble metals (e.g., gold and platinum) from high vacuum metal deposition by electron beam or sputtering. The application and drive of the impurities may be simultaneous or sequential.

### CROSS-REFERENCE TO RELATED APPLICATION

This application claims priority benefit under 35 U.S.C. §119(e) of U.S. Provisional Patent App. No. 61/424,015, filed Dec. 16, 2010, which is hereby incorporated by reference in its entirety.

### BACKGROUND

1. Field

The present application relates to power semiconductors, and, more particularly, to lifetime suppression in power semiconductors such as diodes.

2. Description of the Related Art

Gold and platinum have been used independently in the semiconductor industry to suppress the lifetime of power semiconductors in fast recovery diodes. Each noble metal used independently exhibits both desirable and undesirable electrical characteristics that must be taken into account to provide optimal performance of a given system. For example, when each lifetime suppressor is used independently, the designer is compelled to determine if high temperature characteristics outweigh the need for efficiency. By contrast, certain embodiments described herein simultaneously use combinations of noble metals as a lifetime suppressant while maintaining certain desirable attributes of each noble metal. As power systems evolve to higher density and higher frequency operation, the need for fast, efficient, high-temperature diodes becomes apparent.

### SUMMARY

Certain embodiments combine the use of two or more noble metal impurities (e.g., gold, platinum, palladium, iridium, etc.) to suppress the lifetime of power semiconductors such as diodes. The noble metals may be applied using various methods including, for example, the application of thin films from a liquid suspension of the noble metals (e.g., gold and platinum) and/or alloys thereof onto the wafer and/or the coating the wafer with a layer of the noble metals (e.g., gold and platinum) from high vacuum metal deposition by electron beam or sputtering. The application and drive of the impurities may be simultaneous or sequential.

In some embodiments, a power semiconductor comprises a silicon substrate, a gold dopant, and a platinum dopant. The gold dopant is in the substrate at a concentration of between about 10¹⁴ atoms/cm³ and about 10¹⁸ atoms/cm³ at a depth measured at about 1.5 μm. The platinum dopant is in the substrate at a concentration measured at between about 10¹⁴ atoms/cm³ and about 10¹⁸ atoms/cm³ at a depth measured at about 1.5 μm. A forward voltage of the power semiconductor is at least as low as a forward voltage of a power semiconductor consisting of only gold dopant or only platinum dopant in a substrate. A reverse breakdown voltage of the power semiconductor is at least as high as a reverse breakdown voltage of a power semiconductor consisting of only gold dopant or only platinum in a substrate. A reverse leakage current of the power semiconductor is as low as a reverse leakage current of a power semiconductor consisting of only gold dopant or only platinum in a substrate. A carrier lifetime is shorter than a carrier lifetime of a power semiconductor consisting of only gold dopant or only platinum dopant in a substrate. A reverse recovery time is shorter than a reverse recovery time of a power semiconductor consisting of only gold dopant or only platinum dopant in a substrate.

In some embodiments, a power semiconductor comprises a substrate, a first noble metal in the substrate, and a second noble metal in the substrate. The second noble metal is different than the first metal.

In some embodiments, a method of manufacturing a power semiconductor comprises applying a first noble metal to a substrate; applying a second noble metal to the substrate; and driving the first noble metal and the second noble metal into the substrate.

For purposes of summarizing the invention and the advantages achieved over the prior art, certain objects and advantages of the invention are described herein. Of course, it is to be understood that not necessarily all such objects or advantages need to be achieved in accordance with any particular embodiment. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description having reference to the attached figures, the invention not being limited to any particular disclosed embodiment(s).

### BRIEF DESCRIPTION OF THE DRAWINGS

These and other features, aspects, and advantages of the present disclosure are described with reference to the drawings of certain embodiments, which are intended to illustrate certain embodiments and not to limit the invention.

FIG. 1 illustrates an example concentration profile of gold and platinum after deposition and drive.

FIG. 2 illustrates energy levels of noble metal trap dopants in a lightly doped intrinsic silicon layer.

FIG. 3 is an example embodiment of an axially leaded diode comprising a silicon substrate comprising gold dopant and platinum dopant.

FIG. 3A is a larger view of the elements in the circle 3A in FIG. 3.

Although certain embodiments and examples are described below, those of skill in the art will appreciate that the invention extends beyond the specifically disclosed embodiments and/or uses and obvious modifications and equivalents thereof. Thus, it is intended that the scope of the invention herein disclosed should not be limited by any particular embodiments described below.

### DETAILED DESCRIPTION

Noble metals introduce impurities in the silicon lattice structure, creating recombination sites that suppress carrier lifetime. Each impurity provides a trade-off between performance electrical characteristics that requires the designer to choose a lifetime suppression method that best suits the intended application. Lifetime suppression in semiconductor elements has been limited to the singular use of individual noble metals such as gold and platinum. For example, lifetime suppression with gold can yield desired attributes in reducing reverse recovery characteristics and a low forward voltage. However, gold can have an adverse effect with an increase in reverse leakage that is more pronounced at elevated temperatures. If gold is utilized as the lifetime suppressant, a designer or end user might reduce the operational temperature of the system to gain efficiency without excessive reverse leakage. For another example, lifetime suppression with platinum or palladium can reduce reverse recovery characteristics but can yield higher forward voltage with lower reverse leakage. If platinum or palladium is utilized as the lifetime suppressant, a designer or end user might compromise efficiency (forward voltage) for high temperature operation.

Certain embodiments of power semiconductors described herein comprise two or more noble metal impurities (e.g., gold, platinum, palladium, iridium, etc.). The application of a plurality of noble metals or trap dopants (e.g., gold and platinum) and subsequent impurity drive can gain the benefit of low forward voltage drop from one impurity (e.g., the gold impurity) while maintaining relatively low reverse leakage at elevated temperatures from another impurity (e.g., the platinum impurity). Switch times can be enhanced (e.g., optimized) by the drive temperature that increases recombination sites reducing the turn off and turn on time of the power semiconductor, thus allowing the semiconductor to be used in high frequency and high temperature operations.

Advantages that may be achieved by certain embodiments of the inventions described herein may include, without limitation, suppression of the lifetime of a power semiconductor maintaining the best relationship between forward voltage drop and high temperature reverse leakage.

In some embodiments, a power semiconductor comprises a substrate, a first noble metal in the substrate, and a second noble metal in the substrate. The second noble metal is different than the first metal. In certain such embodiments, the first noble metal is gold and the second noble metal is platinum.

In some embodiments, a power diode consists essentially of a substrate, a first noble metal in the substrate, and a second noble metal in the substrate (e.g., the power semiconductor does not contain substantial amounts of other dopants). The second noble metal is different than the first metal. In certain such embodiments, the first noble metal is gold and the second noble metal is platinum.

Semiconductors such as diodes doped with gold and platinum unexpectedly show improved performance, particularly lower reverse current and faster switching time, over diodes doped only with gold and diodes doped only with platinum driven at a given temperature. The improvements in performance are directly related to the combination of gold and platinum together to shorten carrier lifetime.

At least one aspect of the inventions described herein is the discovery and appreciation that the combined doping of gold and platinum can unexpectedly provide properties that are the “best of both” gold and platinum, or that are at least no worse, than either gold alone or platinum alone. For example, Table 1 shows that for doping with a combination of gold and platinum, the forward voltage (V_{F}) is low (e.g., at least as low as in a diode consisting of only gold dopant), the reverse breakdown voltage (V_{BR}) is higher than gold (e.g., at least as high as in a diode consisting of only gold dopant), the reverse leakage current (I_{R}) is low (e.g., at least as low as in a diode consisting of only platinum dopant), the carrier lifetime is the shortest (e.g., at least as short as in a diode consisting of only gold dopant or only platinum dopant), and the reverse recovery time (T_{RR}) is the shortest (e.g., at least as short as in a diode consisting of only gold dopant or only platinum dopant).

TABLE 1
Tradeoffs for Gold (Au) and Platinum (Pt) Doped Layers

| Property | Au | Pt | Au + Pt |
|---|---|---|---|
| Energy Levels | Ec − | Ev + | Same as |
| | 0.54 eV | 0.42 eV | defined |
| | | | individually |
| Forward Voltage (V_{F}) | Low | Medium | Low |
| Reverse Breakdown | High | Highest | Higher |
| Voltage (V_{BR}) | | | |
| Reverse Leakage | High | Low | Low |
| Current (I_{R}) @ 125° C. | | | |
| Carrier Lifetime | Short | Short | Shortest |
| Reverse Recovery Time (T_{RR}) | Short | Short | Shortest |

Analysis by the applicant indicates that certain of these characteristics may be dependent on temperature. For example, reverse current may be strongly dependent on temperature. For another example, breakdown voltage, which is dependent on the intrinsic region length and doping, should show little dependence on temperature. For yet another example, if avalanche effects are present, there should be greater temperature sensitivity.

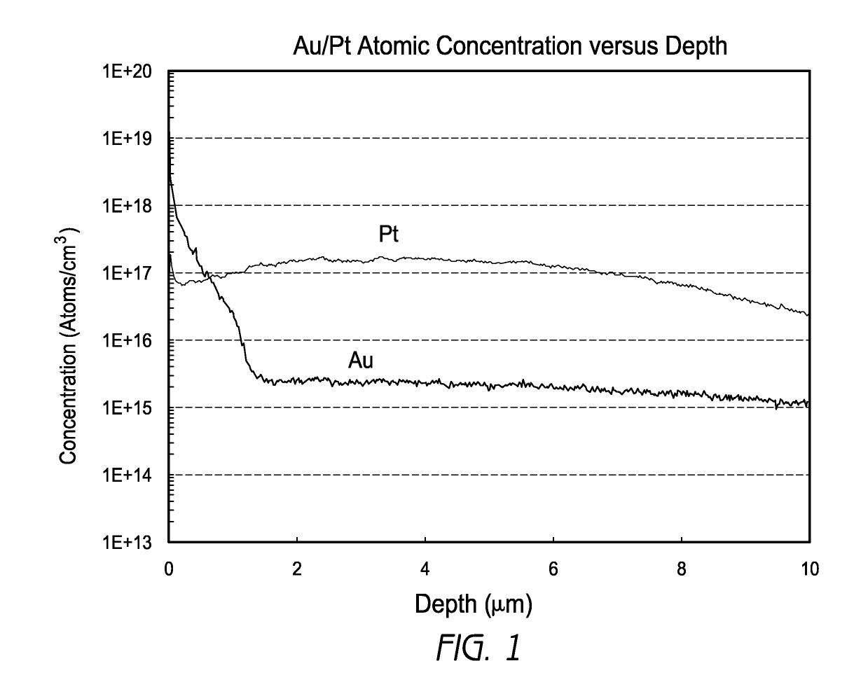

FIG. 1 illustrates an example concentration profile of gold and platinum after deposition and drive, for example as determined by a secondary ion mass spectrometry (SIMS) analysis. The concentration of gold starts at about 10¹⁹/cm³ and becomes substantially constant at about 10¹⁵ atoms/cm³ after a depth of about 1.5 μm. The concentration of platinum starts at about 10¹⁷ atoms/cm³ and stays substantially constant at all depths with a slight decay after a depth of about 4 μm. The concentration may vary laterally across the substrate, for example being higher at ends of die and/or a substrate due to a gettering action of initial diffusion dopants (e.g., phosphorous, boron, and/or arsenic).

The applicant manufactured two 1N5811 150 volt (V) diodes in a silicon-epitaxial substrate: (1) a 1N5811 gold-doped and platinum-doped 150 V diode having gold and platinum concentrations similar to those illustrated in FIG. 1 and (2) a 1N5811 platinum-doped 150 V diode having a platinum concentration similar to that illustrated in FIG. 1. In addition, the applicant purchased (3) a 1N5811 gold-doped 150 V diode having a gold concentration similar to that illustrated in FIG. 1. The applicant then tested the electrical characteristics of the diodes, as described herein with respect to Tables 2-5.

Certain electrical characteristics (e.g., reverse leakage current (I_{R}), reverse recovery time (T_{RR})) may be dependent on the temperature and/or time of the dopant drive. The applicant was able to control the dopant drive time and temperature in the gold-doped and platinum-doped diode and in the platinum-doped diode, and was able to make them identical. For the purchased gold-doped diode, the applicant could not control the dopant drive temperature and time. However, gold-doped diodes generally utilize a higher drive temperature than used for the gold-doped and platinum-doped diode and platinum-doped diode to achieve acceptable T_{RR}. It may be possible to utilize an even higher drive temperature to attempt to match the T_{RR} for the gold-doped and platinum-doped diode and platinum-doped diode, but that might adversely affect I_{R}. For the sake of comparison, the applicant assumed that the driving process for the gold-doped diode was optimized for I_{R} and T_{RR}.

This theory is confirmed by Table 2, which compares example values for a gold-doped and platinum-doped 1N5811 150 V diode, a platinum-doped 1N5811 150 V diode, and a gold-doped 1N5811 150 V diode that were obtained by the applicant manufacturing or obtaining and then testing such diodes. The reverse leakage current (I_{R}) for the gold-doped and platinum-doped diode, measured at 150 V (25° C.) reverse bias, is about 6% that of the gold-doped diode (51.7 nanoamperes (nA)/902 nA). Each of the diodes shows a large increase in current when the temperature is increased to 125° C. At the elevated temperature, the I_{R} for the gold-doped and platinum-doped diode is still about 6% of the gold-doped diode (20.9 microamperes (μA)/346.5 μA). Thus, the reverse leakage current characteristics for a gold-doped and platinum-doped diode are lower than (e.g., significantly improved over) the reverse leakage current characteristics for a gold-doped diode, and are fairly close to the reverse leakage current characteristics for a platinum-doped diode. In general, the lower the reverse leakage current, the more desirable the diode, and the diodes described herein can be used in a wide range of applications in addition to those described herein because they have reverse leakage currents that are almost as low as platinum-doped diodes.

TABLE 2
Reverse Leakage Current (I_{R}) Characteristics for a 150 V Power Diode

| Parameter | I_{R} @ 25° C. | I_{R} @ 125° C. |
|---|---|---|
| Conditions | 150 V_{R} | 150 V_{R} |
| Au/Pt diode | 51.7 nA | 20.9 μA |
| Au diode | 902 nA | 346.5 μA |
| Pt diode | 42.7 nA | 3.9 Ua |

Analysis by the applicant also indicates that forward current has an exponential dependence on the forward voltage. This theory is confirmed by Table 3, which compares example values for a gold-doped and platinum-doped 1N5811 150 V diode, a platinum-doped 1N5811 150 V diode, and a gold-doped 1N5811 150 V diode that were obtained by the applicant manufacturing or obtaining and then testing such diodes. All three diodes show large increases in current for small increases in voltage. For the gold-doped and platinum-doped diode, doubling the current from 3 amperes (A) to 6 A increases the forward voltage only about 7%, from 0.793 V to 0.851 V. Likewise, for the gold-doped diode, doubling the current from 3 A to 6 A increases the forward voltage only about 7%, from 0.798 V to 0.855 V and 7.4% for the platinum-doped diode increasing the forward voltage from 0.810 V to 0.870 V. Thus, the forward voltage characteristics of a gold-doped and platinum-doped diode are at least as good as the forward voltage characteristics of a gold-doped diode. In general, the lower the forward voltage, the more desirable the diode, and the diodes described herein can be used in a wide range of applications in addition to those described herein because they have forward voltages that are lower than the gold-doped diodes.

TABLE 3
Forward Voltage (V_{F}) Characteristics at 25° C. for a
150 V Power Diode

| Parameter | V_{F} | V_{F} | V_{F} |
|---|---|---|---|
| Conditions | 3 A | 4 A | 6 A |
| Au/Pt diode | 0.793 V | 0.816 V | 0.851 V |
| Au diode | 0.798 V | 0.819 V | 0.855 V |
| Pt diode | 0.810 V | 0.833 V | 0.870 V |

Analysis by the applicant also indicates that forward current should be strongly dependent on temperature. As the temperature rises, the forward current should decrease. In turn, the forward voltage should decrease for a constant current. This theory is confirmed by Table 4, which compares example values for a gold-doped and platinum-doped 1N5811 150 V diode, a platinum-doped 1N5811 150 V diode, and a gold-doped 1N5811 150 V diode that were obtained by the applicant manufacturing or obtaining and then testing such diodes. At 4 A, the forward voltage decreases linearly with temperature over the range −65° C. to +125° C. for all three diodes.

TABLE 4
Forward Voltage (V_{F}) Characteristics at 4 A for a 150 V Power Diode

| Parameter | V_{F} | V_{F} | V_{F} |
|---|---|---|---|
| Conditions | −65° C. | 25° C. | 125° C. |
| Au/Pt diode | 0.937 V | 0.816 V | 0.682 V |
| Au diode | 0.940 V | 0.819 V | 0.689 V |
| Pt diode | 0.960 V | 0.833 V | 0.710 V |

Using gold and platinum trap dopants together can improve the switching time significantly over using gold alone. This theory is confirmed by Table 5, which compares example values for a gold-doped and platinum-doped 1N5811 150 V diode, a platinum-doped 1N5811 150 V diode, and a gold-doped 1N5811 150 V diode that were obtained by the applicant manufacturing or obtaining and then testing such diodes. At 25° C., the gold-doped and platinum-doped diode, switching at 20.2 nanoseconds (ns), is about 15% faster than the gold-doped diode, switching at 23.6 ns, and is about 31% faster than the platinum-doped diode, switching at 29.4 ns. A significant improvement in switching time is also seen at 100° C. (32 ns for the gold-doped and platinum-doped diode compared to 36 ns for the gold-doped diode and 43 ns for the platinum-doped diode). While all of the 150 V diodes meet a 30 ns target specification at 25° C., there is a clear advantage to a gold-doped and platinum-doped diode for lifetime kill. In general, the faster the reverse recovery time, the more desirable the diode, and the diodes described herein can be used in a wide range of applications in addition to those described herein because they have reverse recovery times that faster than gold-doped diodes at 25° C. and 100° C.

Table 5 also shows the delta shift in reverse recovery time from 25° C. to 100° C. The gold-doped and platinum-doped diode, having a delta shift of 11.8 ns, is about 5% less than the gold-doped diode, having a delta shift of 12.4 ns, and is about 13% less than the platinum-doped diode, having a delta shift of 13.6 ns. Thus, not only is the gold-doped and platinum-doped diode faster than the gold-doped diode and the platinum-doped diode, but the gold-doped and platinum-doped diode also has a lower delta shift than the gold-doped diode and the platinum-doped diode.

TABLE 5
Reverse Recovery Time (T_{RR}) Characteristics as Measured at
I_{F} = 1.0 A, I_{R} = 1.0 A, and I_{RR} = 0.1 A for a 150 V Power Diode

| Parameter | T_{RR} | T_{RR} | T_{RR} |
|---|---|---|---|
| Conditions | 25° C. | 100° C. | Δ |
| Au/Pt diode | 20.2 ns | 32 ns | 11.8 ns |
| Au diode | 23.6 ns | 36 ns | 12.4 ns |
| Pt diode | 29.4 ns | 43 ns | 13.6 ns |

The noble metals may be applied using various methods including, for example, the application of thin films from a liquid suspension of the noble metals (e.g., gold and platinum) and/or alloys thereof onto the wafer and/or the coating the wafer with a layer of the noble metals (e.g., gold and platinum) from high vacuum metal deposition by electron beam or sputtering. The application and drive of the impurities may be simultaneous or sequential.

In some embodiments in which gold is applied from a liquid suspension, the liquid suspension comprises, for example, GOLD FILM Au-900 or GOLD FILM Au-910, available from Filmtronics, Inc. of Butler, Pa., or GOLD FILM, available from Emulsitone Company of Whippany, N.J. Other gold suspensions are also possible. In some embodiments in which platinum is applied from a liquid suspension, the liquid suspension comprises, for example, PLATINUM FILM Pt-920 or PLATINUM FILM Pt-930, also available from Filmtronics, Inc. of Butler, Pa., or PLATINUM FILM, also available from Emulsitone Company of Whippany, N.J. Other platinum suspensions are also possible. In some embodiments in which gold and platinum are applied from a liquid suspension, the liquid suspension comprises, for example, a pre-mixed solution of a gold suspension and a platinum suspension. In certain such embodiments, the suspensions may be pre-mixed in a volumetric ratio of, for example, about 1:1. Other volumetric ratios are also possible (e.g., between about 1:2 and about 2:1), for example depending on the concentration of the metals in the liquid suspensions and the desired ratio of the impurities. The pre-mixed solution may be spun onto the substrate (e.g., at a speed of about 2,000 rotations per minute (rpm)), densified on a hot plate (e.g., at a temperature of about 150° C.), and then driven into the substrate in a diffusion furnace (e.g., at a temperature of about 940° C.).

In some embodiments, two or more solutions each comprising an impurity may be spun onto the substrate, densified on a hot plate, and then driven into the substrate in a diffusion furnace. In some embodiments, the impurities may be spun onto the substrate and densified on a hot plate in series, and then driven into the substrate in a diffusion furnace together. In certain embodiments, the concentrations of the metals are large enough after densification to supply the desired amount of atomic concentration. It will be appreciated that the solution(s) may also be spun on at different rotational speeds (e.g., between about 500 rpm and about 3,000 rpm), painted on, dried in a specific ambient (e.g., air, argon, hydrogen, etc.), densified at different temperatures (e.g., between about 100° C. and about 400° C., between about 150° C. and about 300° C., etc.), driven in a specific ambient (e.g., nitrogen, argon, hydrogen), driven at different temperatures (e.g., between about 800° C. and about 1,200° C., between about 800° C. and about 1,000° C., etc.), etc.

In some embodiments, the noble metals are applied using a thin film process (e.g., high vacuum metal deposition), in which high purity metals (e.g., at least about 99.999% pure) are applied to the substrate by evaporation or sputtering. The metal application may be a consecutive coating process where the vacuum chamber is not exposed to atmosphere prior to the application of the second metal, for example using a system that configured to evaporate or sputter a first metal (e.g., gold or platinum) and then a second metal (e.g., gold or platinum) without having to open the system and change metal charges. This may advantageously reduce, minimize, or eliminate formation of a barrier layer (e.g., oxide, gold metallic compound, etc.) between the two metal layers. In some embodiments in which gold and platinum are used as impurities, gold is applied first and then platinum is applied second. In certain embodiments, the metals should be thick enough to supply the desired amount of atomic concentration but thin enough to be diffused into the substrate. In some embodiments, the thickness of each metal is between about 200 Å and about 300 Å. In some embodiments, the substrates can be directly transferred from a thin film applicator into a diffusion furnace or drive tube (e.g., at a temperature of about 940° C.).

In some embodiments, the concentrations of the impurities when diffused into the substrate may be approximately or substantially the same. For example, a concentration of gold diffused into silicon may be between about 10¹⁴ atoms/cm³ and about 10¹⁸ atoms/cm³ at a depth of about 1.5 μm and a concentration of platinum diffused into silicon may be between about 10¹⁴ atoms/cm³ and about 10¹⁸ atoms/cm³ at a depth of about 1.5 μm. For another example, a concentration of gold diffused into silicon may be between about 10¹⁴ atoms/cm³ and about 10¹⁷ atoms/cm³ at a depth of about 1.5 μm and a concentration of platinum diffused into silicon may be between about 10¹⁴ atoms/cm³ and about 10¹⁷ atoms/cm³ at a depth of about 1.5 μm. For yet another example, a concentration of gold diffused into silicon may be between about 10¹⁵ atoms/cm³ and about 10¹⁷ atoms/cm³ at a depth of about 1.5 μm and a concentration of platinum diffused into silicon may be between about 10¹⁵ atoms/cm³ and about 10¹⁷ atoms/cm³ at a depth of about 1.5 μm. In some embodiments, the concentration of a first impurity when diffused into the substrate may be greater than the concentration of a second impurity when diffused into the substrate. For example, a concentration of gold diffused into silicon may be between about 10¹⁵ atoms/cm³ and about 10¹⁶ atoms/cm³ at a depth of about 1.5 μm and a concentration of platinum diffused into silicon may be between about 10¹⁶ atoms/cm³ and about 10¹⁸ atoms/cm³ at a depth of about 1.5 μm. Other concentrations are also possible, for example depending on the metals, the substrate, and the solid solubility constants of the metals into the substrate.

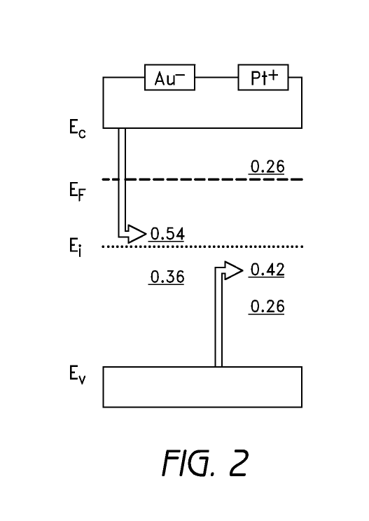

FIG. 2 shows energy levels for gold and platinum in a lightly doped intrinsic silicon layer. The arrows indicate the dominant transition for gold and platinum. The density of gold and platinum dopants is small (10¹⁴/cm³), so the states are discrete energy levels rather than bands. Because the energy levels are not close to either of the bands, they are referred to as traps. A trap has localized interactions with both electrons and holes.

An electron-hole recombination is a two step process. For example, when an electron is captured by a trap, it can later recombine with a hole in the valance band. Gold preferentially traps an electron from the conduction band; platinum preferentially traps a hole from the valence band. Both of these processes are far more efficient than the process in pure silicon, resulting in several orders of magnitude reduction in lifetime.

When both gold and platinum dopants are present, there can also be transitions between the gold and platinum states. This introduces a three step process, where the electron in the gold trap and the hole in the platinum trap recombine. Recombination now has three paths: (1) the independent two-step processes for gold, (2) the independent two-step process for platinum, and (3) the three-step process involving gold and platinum. The increased number of recombination paths can further reduce the lifetime.

Certain embodiments described herein may be used to fabricate a variety of power diodes and other power semiconductors such as, but not limited to, axially leaded diodes, DO-5 diodes, DO-4 diodes, small signal devices, insulated-gate bipolar transistors (IGBTs), thyristors, transistors, metal-oxide-semiconductor field-effect transistors (MOSFETS), etc. and/or other types of semiconductors and/or power semiconductors.

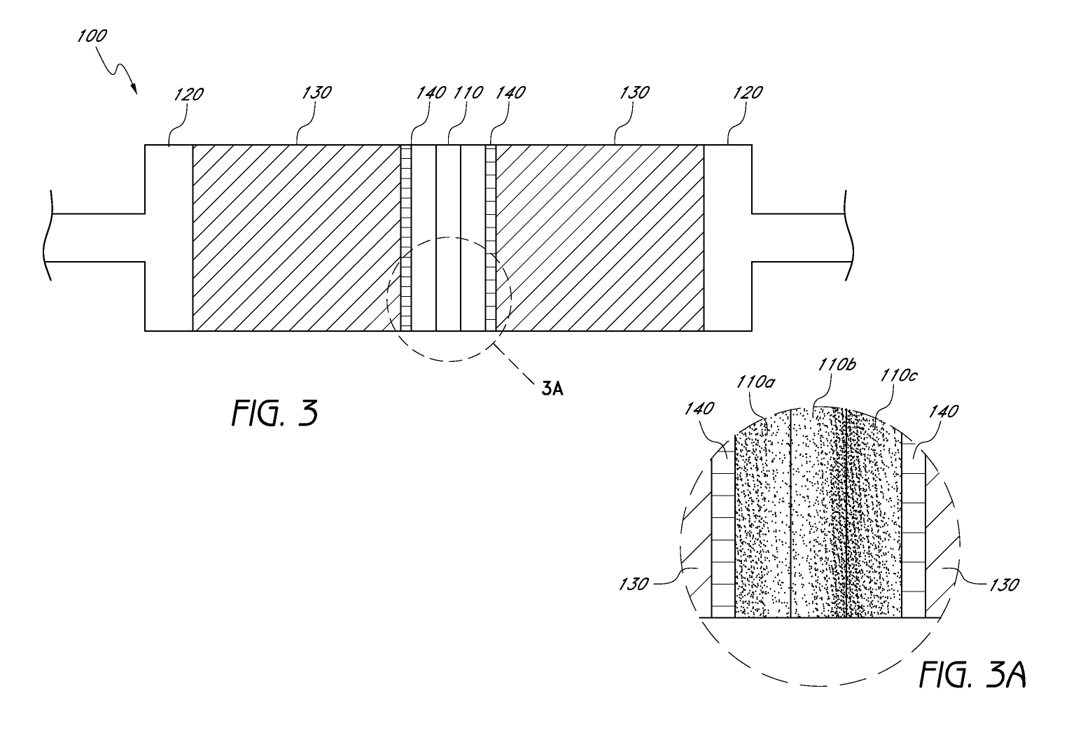

FIG. 3 is an example embodiment of an axially leaded diode assembly 100 comprising a semiconductor 110 (e.g., a silicon die) comprising trap dopants (e.g., gold and platinum). In some embodiments, the semiconductor 110 is connected on each side by an ohmic contact slug-semiconductor attachment 140 to a metal slug 130 (e.g., comprising a refractory metal) that are then bonded to axially-oriented leads 120. FIG. 3A is a larger view of the elements in the circle 3A in FIG. 3. The semiconductor 110 comprises a first resistivity region 110a, a second resistivity region 110b, and a third resistivity region 110c. In the illustrated embodiment, the first resistivity region 110a comprises an N⁺ low-resistivity region, the second resistivity region 110b comprises an N⁻ high-resistivity region, and the third resistivity region 110c comprises a P⁺ low-resistivity region. The varied hatching in FIG. 3A is a relative representation of the Au/Pt lifetime kill atomic concentration.

While the foregoing written description enables one of ordinary skill to make and use what is considered presently to be the best mode thereof, those of ordinary skill will understand and appreciate the existence of variations, combinations, and equivalents of the specific embodiments and methods described herein. The invention should therefore not be limited by the above described embodiments and methods, but by all embodiments and methods within the scope and spirit of the invention. For example, although examples of impurities have been provided primarily as gold and platinum, it will be appreciated that combinations of other lifetime suppressant metals (e.g., Pd, Ir, etc.), as well as combinations of three or more noble metals, may also be used. For another example, although examples of substrates have been provided primarily as silicon, it will be appreciated that other substrates (e.g., Ge, SiGe, GaAs, etc.) may also be used. For yet another example, combinations of methods described herein are also possible (e.g., application of Au from a liquid suspension and thin film application of Pt or Pd).

What is claimed is:

1. A power semiconductor comprising:
a silicon substrate;
gold dopant in the substrate at a concentration of between about 10¹⁴ atoms/cm³ and about 10¹⁷ atoms/cm³ at a depth of about 1.5 μm; and
platinum dopant in the substrate at a concentration of between about 10¹⁴ atoms/cm³ and about 10¹⁷ atoms/cm³ at a depth of about 1.5 μm,
wherein a forward voltage of the power semiconductor is at least as low as a forward voltage of a power semiconductor consisting of only gold dopant in a substrate,
wherein a reverse breakdown voltage of the power semiconductor is at least as high as a reverse breakdown voltage of a power semiconductor consisting of only gold dopant in a substrate,
wherein a reverse leakage current of the power semiconductor is lower than a reverse leakage current of a power semiconductor consisting of only gold dopant in a substrate,
wherein a carrier lifetime is shorter than a carrier lifetime of a power semiconductor consisting of only gold or only platinum dopant in a substrate, and
wherein a reverse recovery time is shorter than a reverse recovery time of a power semiconductor consisting of only gold or only platinum noble metal dopant in a substrate.

2. The power semiconductor of claim 1, wherein the power semiconductor is an axially leaded diode, a DO-5 diode, a DO-4 diode, a small signal device, an insulated-gate bipolar transistor, a thyristor, a transistor, or a metal-oxide-semiconductor field-effect transistor.

3. A power semiconductor comprising:
a substrate;
a first noble metal dopant in the substrate; and
a second noble metal dopant in the substrate, the second noble metal dopant different than the first noble metal dopant.

4. The power semiconductor of claim 3, wherein the first noble metal dopant is gold.

5. The power semiconductor of claim 4, wherein the second noble metal dopant is platinum.

6. The power semiconductor of claim 3, wherein the first noble metal dopant has a first concentration in the substrate and wherein the second noble metal dopant has a second concentration in the substrate, the first concentration substantially the same as the second concentration.

7. The power semiconductor of claim 3, wherein the first noble metal dopant has a first concentration in the substrate and wherein the second noble metal dopant has a second concentration in the substrate, the first concentration greater than the second concentration.

8. The power semiconductor of claim 3, further comprising a third noble metal dopant in the substrate.

9. The power semiconductor of claim 3, wherein a forward voltage of the power semiconductor is at least as low as a forward voltage of a power semiconductor consisting of only one noble metal dopant in a substrate.

10. The power semiconductor of claim 3, wherein a reverse breakdown voltage of the power semiconductor is at least as high as a reverse breakdown voltage of a power semiconductor consisting of only gold dopant in a substrate.

11. The power semiconductor of claim 3, wherein a reverse leakage current of the power semiconductor is lower than a reverse leakage current of a power semiconductor consisting of only gold dopant in a substrate.

12. The power semiconductor of claim 3, wherein a carrier lifetime is shorter than a carrier lifetime of a power semiconductor consisting of only one noble metal dopant in a substrate.

13. The power semiconductor of claim 3, wherein a reverse recovery time is shorter than a reverse recovery time of a power semiconductor consisting of only one noble metal dopant in a substrate.

14. The power semiconductor of claim 3, wherein the power semiconductor is an axially leaded diode, a DO-5 diode, a DO-4 diode, a small signal device, an insulated-gate bipolar transistor, a thyristor, a transistor, or a metal-oxide-semiconductor field-effect transistor.

15. A method of manufacturing a power semiconductor, the method comprising:
applying a first noble metal to a substrate;
applying a second noble metal to the substrate; and
driving the first noble metal and the second noble metal into the substrate.

16. The method of claim 15, wherein applying the first noble metal to the substrate and applying the second noble metal to the substrate comprise:
spinning a first liquid suspension comprising the first noble metal onto the substrate;
densifying the first liquid suspension,
after densifying the first liquid suspension, spinning a second liquid suspension comprising the second noble metal onto the substrate; and
densifying the second liquid suspension, wherein driving the first noble metal and the second noble metal into the substrate is after densifying the first liquid suspension and densifying the second liquid suspension.

17. The method of claim 15, wherein applying the first noble metal to the substrate and applying the second noble metal to the substrate comprise:
spinning a liquid suspension comprising the first noble metal and the second noble metal onto the substrate; and
densifying the liquid suspension, wherein driving the first noble metal and the second noble metal into the substrate is after densifying the liquid suspension.

18. The method of claim 17, wherein applying the liquid suspension to the substrate comprises mixing a first liquid suspension comprising the first noble metal and a second liquid suspension comprising the second noble metal.

19. The method of claim 18, wherein mixing the first liquid suspension and the second liquid suspension comprises mixing in a volumetric ratio between about 1:2 and about 2:1.

20. The method of claim 15, wherein applying the first noble metal to the substrate and applying the second noble metal to the substrate comprise:
depositing the first noble metal in a vacuum chamber,
after depositing the first noble metal, depositing the second noble metal in the vacuum chamber.
